(19) United States
(12) Patent Application Publication
(10) Pub. No.: US 2026/0123218 A1
(43) Pub. Date: Apr. 30, 2026

(54) DISPLAY PANEL AND DISPLAY APPARATUS

(71) Applicant: HKC CORPORATION LIMITED, SHENZHEN (CN)

(72) Inventors: Wenyu YI, SHENZHEN (CN); Zhonglin CAO, SHENZHEN (CN); Lidan YE, SHENZHEN (CN)

(73) Assignee: HKC CORPORATION LIMITED, SHENZHEN (CN)

(21) Appl. No.: 19/369,228

(22) Filed: Oct. 26, 2025

(30) Foreign Application Priority Data
Oct. 31, 2024 (CN) 202411550218.4

(51) Int. Cl. H10K 59/131; H10K 59/35

(52) U.S. Cl. CPC H10K 59/131; H10K 59/353

(57) ABSTRACT

A display panel and a display apparatus may be provided in the present application. In a specific arrangement configuration of sub-pixels of the present application, three anode-electrode vias for each repeating unit may be arranged in a straight line in a preset direction, so that the three anode-electrode vias may be arranged in three rows and one column. Alternatively, two anode-electrode vias for a first pixel row may be arranged in a straight line in a first direction, and an anode-electrode via for a second pixel row and one anode-electrode via for the first pixel row may be arranged in a straight line in a second direction, such that the three anode-electrode vias may be arranged in two rows and two columns.

### CROSS REFERENCE TO RELATED APPLICATIONS

This application claims priority to Chinese Patent Application No. 202411550218.4, filed on Oct. 31, 2024, which is herein incorporated by reference in its entirety.

### TECHNICAL FIELD

The present disclosure relates to the field of display technologies, and in particular to a display panel and a display apparatus.

### BACKGROUND

An organic light-emitting diode (OLED) display apparatus is a device that is configured to achieve graphic display by a reversible color change phenomenon of organic semiconductor materials driven by electric current. The OLED display apparatus may have advantages such as ultra-light weight, ultra-thinness, high brightness, wide viewing angle, low voltage, low power consumption, fast response, high definition, shock resistance, bendability, low cost, simple process, less raw material usage, high luminous efficiency, and a wide temperature range. Therefore, the OLED display technology is regarded as the most promising new-generation display technology.

In the related art, the anode-electrode vias of the OLED display apparatus are generally arranged at central positions of sub-pixels. This arrangement manner of the anode-electrode vias may increase via-drilling paths, thereby reducing an efficiency of via-drilling.

### SUMMARY

A first technical scheme adopted by the present disclosure is to provide a display panel. The display panel may include: a silicon-based driving substrate; and, a light-emitting carrier board. The light-emitting carrier board may be configured to be bonded to the silicon-based driving substrate. The light-emitting carrier board may include: a glass substrate; and, a plurality of arrayed repeating units. The glass substrate may include a plurality of anode-electrode vias. The plurality of arrayed repeating units may be arranged on a side surface of the glass substrate away from the silicon-based driving substrate. Each repeating unit may include three sub-pixels with mutually different colors. The sub-pixels and the anode-electrode vias may be arranged in one-to-one correspondence. The three sub-pixels with mutually different colors may be defined as a first sub-pixel, a second sub-pixel, and a third sub-pixel, respectively. In each of the repeating units, the first sub-pixel and the second sub-pixel may be arranged in a first direction to form a first pixel row. The third sub-pixel may extend in the first direction to form a second pixel row. The first pixel row and the second pixel row may be juxtaposed in a second direction. The first direction may intersect with the second direction. The three anode-electrode vias for each repeating unit may be arranged in a straight line in a preset direction, the preset direction may be the first direction or the second direction; or, in each of the repeating units, two anode-electrode vias for the first pixel row may be arranged in a straight line in the first direction, and the anode-electrode via for the second pixel row and one anode-electrode via for the first pixel row are arranged in a straight line in the second direction.

A second technical solution adopted by the present disclosure is to provide a display apparatus. The display apparatus may include a mother board and a display panel. The display panel may include: a silicon-based driving substrate; and, a light-emitting carrier board. The light-emitting carrier board may be configured to be bonded to the silicon-based driving substrate. The light-emitting carrier board may include: a glass substrate; and, a plurality of arrayed repeating units. The glass substrate may include a plurality of anode-electrode vias. The plurality of arrayed repeating units may be arranged on a side surface of the glass substrate away from the silicon-based driving substrate. Each repeating unit may include three sub-pixels with mutually different colors. The sub-pixels and the anode-electrode vias may be arranged in one-to-one correspondence. The three sub-pixels with mutually different colors may be defined as a first sub-pixel, a second sub-pixel, and a third sub-pixel, respectively. In each of the repeating units, the first sub-pixel and the second sub-pixel may be arranged in a first direction to form a first pixel row. The third sub-pixel may extend in the first direction to form a second pixel row. The first pixel row and the second pixel row may be juxtaposed in a second direction. The first direction may intersect with the second direction. The three anode-electrode vias for each repeating unit may be arranged in a straight line in a preset direction, the preset direction may be the first direction or the second direction; or, in each of the repeating units, two anode-electrode vias for the first pixel row may be arranged in a straight line in the first direction, and the anode-electrode via for the second pixel row and one anode-electrode via for the first pixel row are arranged in a straight line in the second direction.

### BRIEF DESCRIPTION OF THE DRAWINGS

To more clearly illustrate the technical solutions in embodiments of the present disclosure, the drawings required in the description of the embodiments will be briefly introduced below. Obviously, the drawings in the following description are only some embodiments of the present disclosure. For those of ordinary skills in the art, other drawings could be obtained based on these drawings without creative efforts.

FIG. 1 is a schematic structural diagram of a display panel in the related art.

FIG. 2 is a schematic structural diagram of a first embodiment of the display panel according to the present disclosure.

FIG. 3 is a schematic cross-sectional structural diagram of an embodiment in a direction E-E of FIG. 2.

FIG. 4 is a schematic structural diagram of a second embodiment of the display panel according to the present disclosure.

FIG. 5 is a schematic structural diagram of a third embodiment of the display panel according to the present disclosure.

FIG. 6 is a schematic structural diagram of a fourth embodiment of the display panel according to the present disclosure.

FIG. 7 is a schematic cross-sectional structural diagram of an embodiment in a direction F-F of FIG. 6.

FIG. 8 is a schematic structural diagram of a fifth embodiment of the display panel according to the present disclosure.

FIG. 9 is a schematic structural diagram of an embodiment of a display apparatus according to the present disclosure.

### DETAILED DESCRIPTION

The technical scheme of embodiments of the present disclosure is described in detail below in conjunction with the accompanying drawings.

In the following description, specific details such as particular system structures, interfaces, techniques, etc., are presented for the purpose of illustration and not for the purpose of limitation, thereby facilitating a thorough understanding of the present disclosure.

Technical schemes in embodiments of the present disclosure will be described clearly and thoroughly in connection with accompanying drawing of the embodiments of the present disclosure. Obviously, the described embodiments are only a part of the embodiments, but not all of them. All other embodiments by a person of ordinary skills in the art based on embodiments of the present disclosure without creative efforts should all be within the protection scope of the present disclosure.

The terms “first”, “second”, and “third” in the present disclosure are only for the purpose of description, and should not be construed as indicating or implying relative importance or implicitly indicating the number of technical features referred to. Therefore, the features defined with “first”, “second”, and “third” may explicitly or implicitly include at least one of the features. In the description of the present disclosure, “a plurality of” means at least two, such as two, three, etc., unless otherwise specifically defined. All directional indicators (such as up, down, left, right, front, back . . . ) in embodiments of the present disclosure are only used to explain a motion state, a relative positional relationship between the components in a specific posture (as illustrated in the drawings). If the specific posture changes, then the directional indication will change accordingly. In addition, the terms “include”, “comprise” and any variations thereof are intended to cover non-exclusive inclusion. For example, a process, a method, a system, a product, or a device that includes a series of operations or units is not limited to the listed operations or units, but optionally includes unlisted operations or units, or optionally also includes other operations or units inherent to these processes, methods, products or devices.

Reference to “embodiments” herein means that, a specific feature, structure, or characteristic described in conjunction with the embodiments may be included in at least one embodiment of the present disclosure. The appearance of this phrase in various locations in the specification does not necessarily refer to the same embodiment, nor is it an independent or alternative embodiment mutually exclusive with other embodiments. Those of ordinary skills in the art may explicitly and implicitly understand that, the embodiments described herein may be combined with other embodiments.

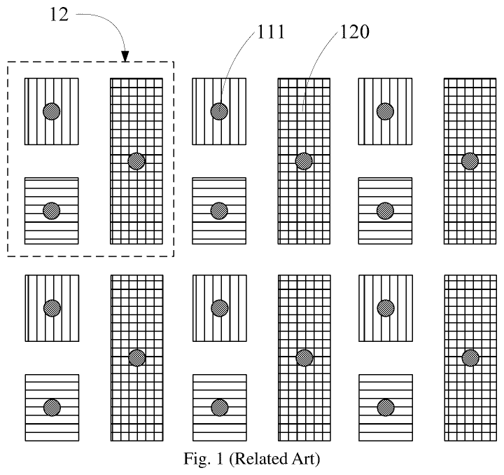

As illustrated in FIG. 1, FIG. 1 is a schematic structural diagram of a display panel in the related art.

In the related art, an anode-electrode via 111 may be located at a very central position of a sub-pixel 120. One sub-pixel 120 may match with one anode-electrode via 111. Three sub-pixels 120 may be arranged in a pyramidical pattern to form a pixel unit (i.e., a repeating unit 12). The three anode-electrode vias 111 for each pixel unit may be arranged among three rows and two columns. This via-drilling pattern for the anode-electrode vias 111 may involve more paths, thereby increasing the via-drilling time and reducing via-drilling efficiency.

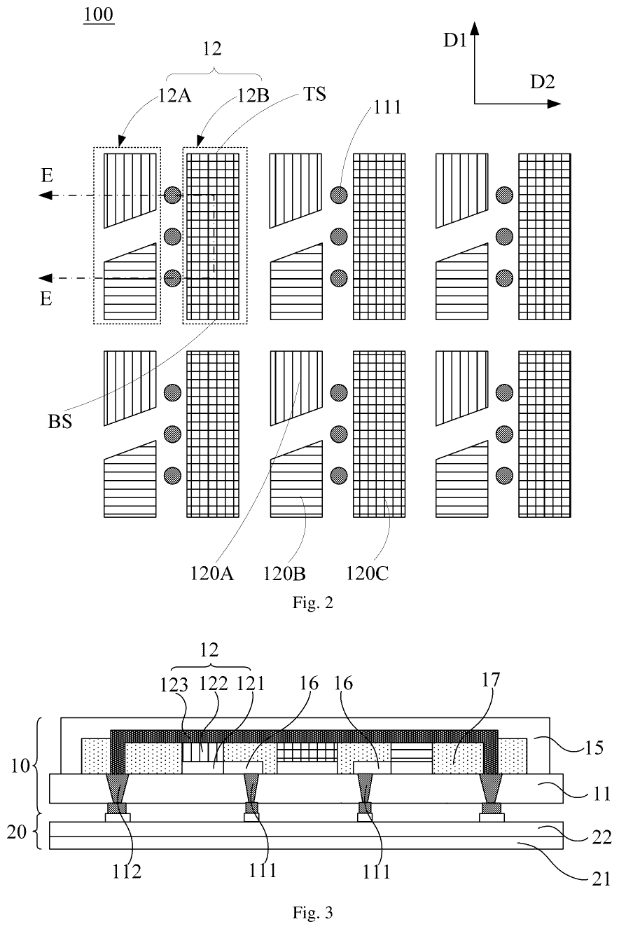

As illustrated in FIG. 2 and FIG. 3, FIG. 2 is a schematic structural diagram of the display panel according to a first embodiment of the present disclosure, and FIG. 3 is a schematic cross-sectional structural diagram of an embodiment in a direction E-E of FIG. 2.

To solve the above-mentioned technical problem, the present disclosure may provide a display panel 100. The display panel 100 may include a silicon-based driving substrate 20 and a light-emitting carrier board 10. The light-emitting carrier board 10 may be bonded to the silicon-based driving substrate 20. The light-emitting carrier board 10 may include a glass substrate 11 and a plurality of arrayed repeating units 12. The glass substrate 11 may include a plurality of anode-electrode vias 111. The plurality of arrayed repeating units 12 may be arranged on a side surface of the glass substrate 11 away from the silicon-based driving substrate 20. Each repeating unit 12 may include three sub-pixels 120 with mutually different colors. The sub-pixels 120 and the anode-electrode vias 111 may be arranged in one-to-one correspondence. The three sub-pixels 120 with mutually different colors may be defined as a first sub-pixel 120A, a second sub-pixel 120B, and a third sub-pixel 120C, respectively. In each repeating unit 12, the first sub-pixel 120A and the second sub-pixel 120B may be arranged in a first direction D1 to form a first pixel row 12A. The third sub-pixel 120C may extend in the first direction D1 to form a second pixel row 12B. The first pixel row 12A and the second pixel row 12B may be arranged in a second direction D2. The first direction D1 may intersect the second direction D2. Herein, the three anode-electrode vias 111 for each repeating unit 12 may be arranged in a straight line in a preset direction, the preset direction may be the first direction D1 or the second direction D2; or, in each repeating unit 12, the two anode-electrode vias 111 for the first pixel row 12A may be arranged in a straight line in the first direction D1, and the anode-electrode via 111 for the second pixel row 12B and one anode-electrode via 111 for the first pixel row 12A may be arranged in a straight line in the second direction D2.

In a specific arrangement configuration of the sub-pixel 120 of the present disclosure, the three anode-electrode vias 111 for each repeating unit 12 may be arranged in a straight line in the preset direction, so that the three anode-electrode vias 111 may be arranged in or distributed among three rows and one column, thereby reducing the via-drilling paths in the column direction and improving the via-drilling efficiency. Alternatively, the two anode-electrode vias 111 for the first pixel row 12A may be arranged in the straight line in the first direction D1, and the anode-electrode via 111 for the second pixel row 12B and one anode-electrode via 111 for the first pixel row 12A may be arranged in the straight line in the second direction D2, such that the three anode-electrode vias 111 may be arranged in or distributed among two rows and two columns, thereby reducing the via-drilling paths in the row direction, optimizing the via-drilling path of the anode-electrode vias 111 and increasing the via-drilling efficiency.

The silicon-based driving substrate 20 may include a silicon-based substrate 21 and a driving circuit layer 22. The driving circuit layer 22 may be arranged on a side of the silicon-based substrate 21 close to the light-emitting carrier board 10.

The silicon-based substrate 21 may refer to a base plate based on monocrystalline silicon material.

The driving circuit layer 22 may include an active driving circuit (not illustrated in the drawings) integrated on the silicon-based substrate 21 through a complementary metal-oxide-semiconductor (CMOS) process.

By separately manufacturing the silicon-based driving substrate 20 and the light-emitting carrier board 10, the manufacturing efficiency may be increased. Additionally, an impact of an evaporation process on the silicon-based driving substrate 20 may be avoided, damage to the silicon-based driving substrate 20 may be reduced. In other words, from a perspective view of process, by separately manufacturing the silicon-based driving substrate 20 and the light-emitting carrier board 10, not only a manufacturing yield may be increased, the cost may also be reduced.

The glass substrate 11 may further include a cathode-electrode via 112. The cathode-electrode via 112 may be spaced apart from the anode-electrode via 111. A cathode electrode 123 of the sub-pixel 120 may be electrically connected to the silicon-based driving substrate 20 through the cathode-electrode via 112. Both the anode-electrode via 111 and the cathode-electrode via 112 may penetrate the glass substrate 11.

The anode-electrode via 111 may be a straight through-hole or a non-straight through-hole. For example, a cross-section of the anode-electrode via 111 in a direction perpendicular to the glass substrate 11 may have a rectangular, trapezoidal, or parallelogram shape, or other shapes. Similarly, the cathode-electrode via 112 may be a straight through-hole or a non-straight through-hole.

In the present embodiment, both the anode-electrode via 111 and the cathode-electrode via 112 may be straight through-holes, thereby reducing current paths and facilitating via preparation.

Each of the cathode-electrode via 112 and the anode-electrode via 111 may include a through-hole and conductive material filled in the through-hole. The conductive materials filled in the anode-electrode via 111 and the cathode-electrode via 112 may be not limited herein and may be selected according to actual needs.

The through-hole in any of the cathode-electrode via 112 and the anode-electrode via 111 may be prepared by a through-glass via (TGV) technology.

In comparation with a through-silicon via technology, the through-glass via technology may have advantages of excellent high-frequency electrical characteristics, low cost, simple process flow, and strong mechanical stability.

Compared with the related art in which the sub-pixels 120 are prepared on the silicon-based driving substrate 20 and electrically connected to the silicon-based driving substrate 20 through a through-silicon via, in the present disclosure, the sub-pixels 120 may be arranged on the glass substrate 11, and the sub-pixels 120 may be bonded to the silicon-based driving substrate 20 through a through-glass via, the cost may be reduced, the high-frequency electrical characteristic may be increased.

A size relationship between the cathode-electrode via 112 and the anode-electrode via 111 may be not limited herein, and may be selected according to actual needs.

In some embodiments, a ratio of a size of a single anode-electrode via 111 to that of the sub-pixel 120 corresponding to the single anode-electrode via 111 may range from ¼ to ½, ensuring a through-hole yield of the anode-electrode via 111 and a conductivity between an anode electrode 121 of the sub-pixel 120 and the anode-electrode via 111 without affecting a pixel aperture of the sub-pixel 120.

In some embodiments, the ratio of the size of the single anode-electrode via 111 to that of the sub-pixel 120 corresponding to the single anode-electrode via 111 may also be another value, which is not unnecessarily limited herein and may be selected per actual requirements.

In some embodiments, in a direction parallel to the glass substrate 11, a cross-section of the anode-electrode via 111 may be a regular shape or an irregular shape, which is not unnecessarily limited herein and may be selected per actual requirements. The regular shape may such as be circular, triangular, rhombic, rectangular, hexagonal, or the like, which is not unnecessarily limited herein and may be selected per actual requirements.

In the present embodiment, in the direction parallel to the glass substrate 11, the cross-section of the anode-electrode via 111 may be circular, thereby facilitating uniform distribution of contact current.

The sub-pixel 120 may be an OLED. The sub-pixel 120 may include the anode electrode 121, a light-emitting layer 122, and the cathode electrode 123 stacked in sequence. The anode electrode 121 may be arranged on a side surface of the glass substrate 11 away from the silicon-based driving substrate 20.

In some embodiments, a size of the sub-pixel 120 may range from 6 μm to 15 μm. The size of the sub-pixel 120 may also be another value.

In some embodiments, the first sub-pixel 120A may be a red sub-pixel 120, the second sub-pixel 120B may be a green sub-pixel 120, and the third sub-pixel 120C may be a blue sub-pixel 120.

In some embodiments, the sub-pixel 120 may also be another color, and the specific color may be selected based on the actual needs.

In some embodiments, in the direction parallel to the glass substrate 11, the repeating unit 12, the first pixel row 12A, and the second pixel row 12B may be all rectangular or all parallelogram-shaped. The first sub-pixel 120A and the third sub-pixel 120C may be centrally symmetrically arranged with respect to each other. The row direction of the repeating unit 12 may be the second direction D2, and the column direction of the repeating unit 12 may be the first direction D1.

In some other embodiments, the first sub-pixel 120A and the second sub-pixel 120B may not be centrally symmetrically arranged with respect to each other, as long as the first pixel row 12A and the second pixel row 12B can form a rectangle or a parallelogram.

A row direction of the repeating unit 12 may be the second direction D2, and a column direction of the repeating unit 12 may be the first direction D1. In this way, the plurality of anode-electrode vias 111 for each column of repeating units 12 may be arranged in one column in the first direction D1, and the plurality of anode-electrode vias 111 for each row of repeating units 12 may be arranged among three rows in the first direction D1, thereby reducing the via-drilling paths of the anode-electrode vias 111 in the column direction and thus increasing the via-drilling efficiency. The three anode-electrode vias 111 for the repeating unit 12 may be equidistantly spaced in the first direction D1, and the anode-electrode vias 111 may be uniformly arranged, thereby increasing the via-drilling efficiency.

In the present embodiment, in the direction parallel to the glass substrate 11, the repeating unit 12, the first pixel row 12A, and the second pixel row 12B may be all rectangular. The first direction D1 may be perpendicular to the second direction D2.

In some embodiments, in the direction parallel to the glass substrate 11, the sub-pixel 120 may be arranged in a misaligned manner with respect to the anode-electrode via 111 for the sub-pixel 120. The three anode-electrode vias 111 for each repeating unit 12 may be all located between the first pixel row 12A and the second pixel row 12B, and arranged in a straight line in the first direction D1. The three anode-electrode vias 111 for the repeating unit 12 may be equidistantly spaced in the first direction D1, thereby facilitating preparation of the anode-electrode vias 111.

Specifically, the anode-electrode via 111 may be located on a side edge of the matched sub-pixel 120. The anode-electrode via 111 for the first sub-pixel 120A may be located on a side of the first sub-pixel 120A close to the third sub-pixel 120C. The anode-electrode via 111 for the second sub-pixel 120B may be located on a side of the second sub-pixel 120B close to the third sub-pixel 120C. The anode-electrode via 111 for the third sub-pixel 120C may be located on a side of the third sub-pixel 120C close to the first pixel row 12A.

In some embodiments, a side edge of the first sub-pixel 120A away from the second sub-pixel 120B may be aligned with a first side edge TS of the third sub-pixel 120C in the second direction D2. A side edge of the second sub-pixel 120B away from the first sub-pixel 120A may be aligned with a second side edge BS of the third sub-pixel 120C in the second direction D2. The first side edge TS and the second side edge BS may be oppositely arranged in the first direction D1. The anode-electrode via 111 for the first sub-pixel 120A, the anode-electrode via 111 for the third sub-pixel 120C, and the anode-electrode via 111 for the second sub-pixel 120B may be sequentially located at a ¼ position, a 2/4 position, and a ¾ position of the third sub-pixel 120C in the first direction D1, thereby reducing a spacing distance between the anode-electrode via 111 and the matched sub-pixel 120, shortening a cross-line length of an electrical connection between the anode electrode 121 of the sub-pixel 120 and the anode-electrode via 111, and improving the via-drilling efficiency.

In the present embodiment, the first sub-pixel 120A and the second sub-pixel 120B may be centrally symmetrically arranged with respect to each other. In the direction parallel to the glass substrate 11, both the first sub-pixel 120A and the second sub-pixel 120B may be trapezoidal, and the third sub-pixel 120C may be rectangular.

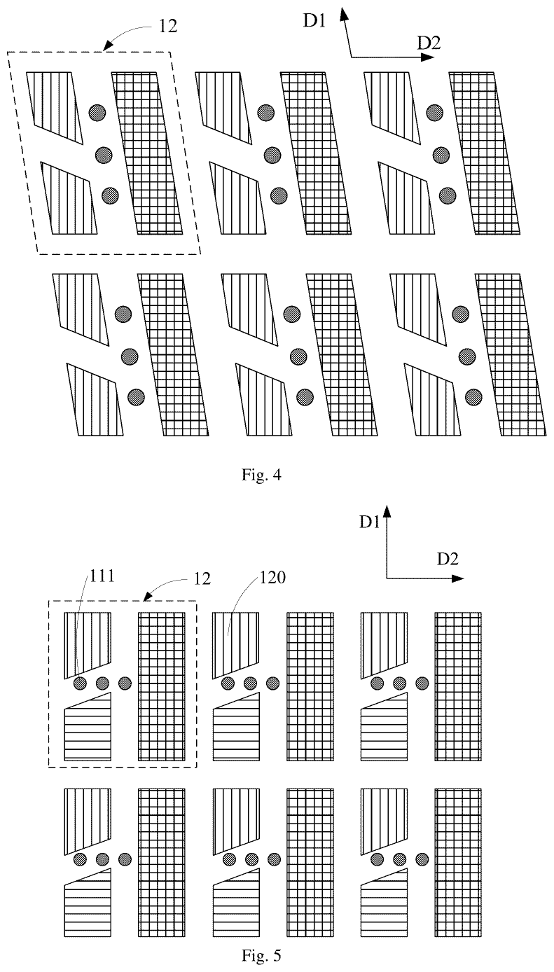

As illustrated in FIG. 2 to FIG. 4, FIG. 4 is a schematic structural diagram of a second embodiment of the display panel according to the present disclosure.

In some embodiments, as illustrated in FIG. 4, in the direction parallel to the glass substrate 11, both the first sub-pixel 120A and the second sub-pixel 120B may be trapezoidal, the repeating unit 12, the first pixel row 12A, and the second pixel row 12B may be all parallelogram-shaped. The first direction D1 may be not perpendicular to the second direction D2. One side edge of the parallelogram may extend in the first direction D1, and another side edge of the parallelogram may extend in the second direction D2.

The display panel 100 may further include an anode electrode extension portion 16. The anode electrode extension portion 16 may be arranged in one-to-one correspondence with the anode-electrode vias 111. The anode electrode extension portion 16 and the anode electrode 121 may be formed by patterning a same conductive layer, thereby simplifying the preparation process. The anode electrode 121 may be electrically connected to the anode-electrode via 111 through the anode electrode extension portion 16. Compared with the design in which the sub-pixel 120 cover a matched anode-electrode via 111, the design in which the anode-electrode via 111 is arranged in a misaligned manner with respect to the matched sub-pixel 120 may better avoid an impact of the anode-electrode via 111 on a film uniformity of the light-emitting layer 122 of the sub-pixel 120, and may better increase light-emitting effect of the sub-pixel 120.

As illustrated in FIG. 2 to FIG. 5, FIG. 5 is a schematic structural diagram of a third embodiment of the display panel according to the present disclosure.

The third embodiment of the display panel 100 according to the present disclosure may be basically similar in structure to the first embodiment according to the present disclosure, except that: the three anode-electrode vias 111 for each repeating unit 12 may be arranged in a row in the second direction D2.

In some embodiments, in the direction parallel to the glass substrate 11, the sub-pixel 120 may be arranged in a misaligned manner with respect to the anode-electrode via 111 for the sub-pixel 120. The three anode-electrode vias 111 for each repeating unit 12 may be arranged in a row in the second direction D2. Two anode-electrode vias 111 for the first pixel row 12A may be located between the first sub-pixel 120A and the second sub-pixel 120B. The anode-electrode via 111 for the third sub-pixel 120C may be located between the first pixel row 12A and the second pixel row 12B.

In some embodiments of the present disclosure, the plurality of anode-electrode vias 111 for each row of repeating units 12 may be arranged in one row in the second direction D2, and the plurality of anode-electrode vias 111 for each column of repeating units 12 may be arranged among three columns in the first direction D1, thereby reducing the via-drilling paths of the anode-electrode vias 111 in the row direction and thus increasing the via-drilling efficiency.

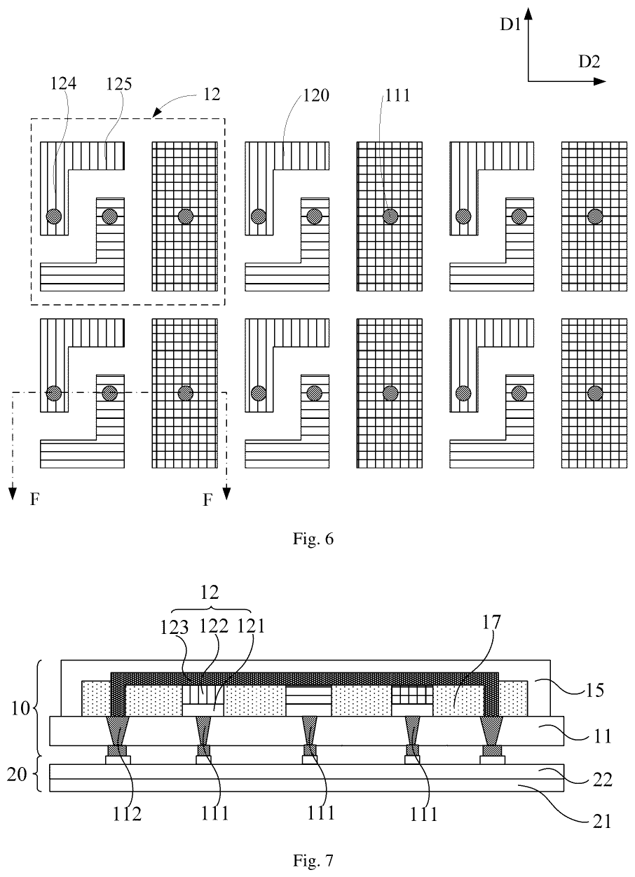

As illustrated in FIG. 2 to FIG. 7, FIG. 6 is a schematic structural diagram of a fourth embodiment of the display panel according to the present disclosure, FIG. 7 is a schematic cross-sectional structural diagram of an embodiment in a direction F-F of FIG. 6.

The fourth embodiment of the display panel 100 according to the present disclosure may be basically similar in structure to the third embodiment according to the present disclosure, except that: the anode-electrode via 111 for the sub-pixel 120 may be covered by the sub-pixel 120. Each of the projection patterns of the first sub-pixel 120A and the second sub-pixel 120B may be L-shaped. An orthographic projection of the first sub-pixel 120A in the second direction D2 may be partially coincide with an orthographic projection of the second sub-pixel 120B in the second direction D2.

In some embodiments, the anode-electrode via 111 for the sub-pixel 120 may be covered by the sub-pixel 120. The three anode-electrode vias 111 for each repeating unit 12 may be arranged in a row in the second direction D2. Each of the projection patterns of the first sub-pixel 120A and the second sub-pixel 120B onto the glass substrate 11 may be L-shaped. An orthographic projection of the first sub-pixel 120A in the second direction D2 may be partially coincide with an orthographic projection of the second sub-pixel 120B in the second direction D2.

A language “the sub-pixel 120 covers the matched anode-electrode via 111” means that, an orthographic projection pattern of the anode-electrode via 111 onto the sub-pixel 120 may be entirely within the sub-pixel 120.

When the sub-pixel 120 is designed to cover the matched anode-electrode via 111, the anode electrode extension portion 16 may be not required, and the anode electrode 121 of the sub-pixel 120 may be directly in contact with the anode-electrode via 111, thereby simplifying the preparation process.

Each sub-pixel 120 in the first pixel row 12A may include a first extension portion 124 and a second extension portion 125. The first extension portion 124 may extend in the first direction D1. The second extension portion 125 may extend in the second direction D2. One end of the first extension portion 124 may be connected to one end of the second extension portion 125 to form an L-shaped structure. The first extension portion 124 may cover the matched anode-electrode via 111.

An orthographic projection of the first extension portion 124 of the first extension portion 124 in the second direction D2 may be partially coincide with an orthographic projection of the first extension portion 124 of the second sub-pixel 120B in the second direction D2. In this way, the two anode-electrode vias 111 for the first pixel row 12A may be arranged in a row in the second direction D2.

In some embodiments of the present disclosure, the plurality of anode-electrode vias 111 for each row of repeating units 12 may be arranged in one row in the second direction D2, and the plurality of anode-electrode vias 111 for each column of repeating units 12 may be arranged among three columns in the first direction D1, thereby reducing the via-drilling paths of the anode-electrode vias 111 in the row direction and thus increasing the via-drilling efficiency.

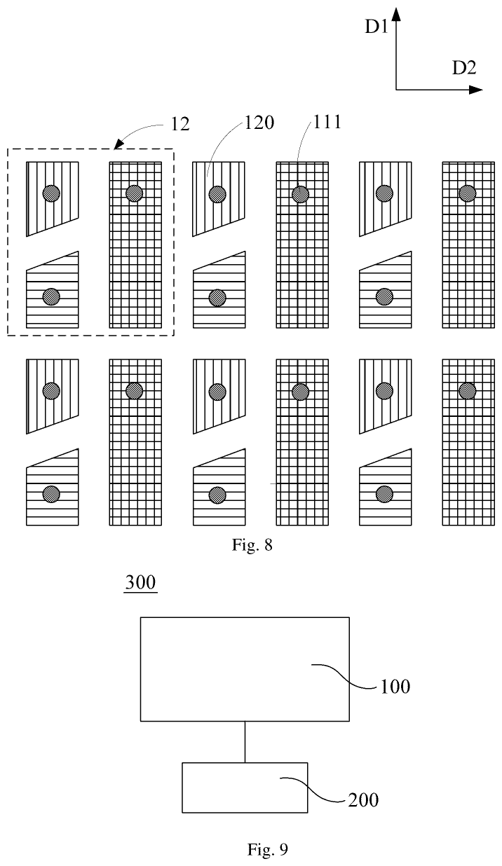

As illustrated in FIG. 2 to FIG. 8, FIG. 8 is a schematic structural diagram of a fifth embodiment of the display panel according to the present disclosure.

The fifth embodiment of the display panel 100 according to the present disclosure may be basically similar in structure to the first embodiment according to the present disclosure, except that: the two anode-electrode vias 111 for the first pixel row 12A may be arranged in a straight line in the first direction D1. The anode-electrode via 111 for the third sub-pixel 120C and the anode-electrode via 111 for one sub-pixel 120 in the first pixel row 12A may be arranged in a row in the second direction D2.

In some embodiments, the anode-electrode via 111 for the sub-pixel 120 may be covered by the sub-pixel 120. The two anode-electrode vias 111 for the first pixel row 12A may be arranged in a straight line in the first direction D1. The anode-electrode via 111 for the third sub-pixel 120C and the anode-electrode via 111 for the first sub-pixel 120A may be arranged in a row along the second direction D2. Alternatively, the anode-electrode via 111 for the third sub-pixel 120C and the anode-electrode via 111 for the second sub-pixel 120B may be arranged in a row along the second direction D2.

In the present embodiment, a case where the anode-electrode via 111 for the third sub-pixel 120C and the anode-electrode via 111 for the first sub-pixel 120A are arranged in a row in the second direction D2 may be taken as an example for description.

In some embodiments, in the first pixel row 12A, the anode-electrode via 111 for the sub-pixel 120 may be located at a geometric center of a light-emitting region of the matched sub-pixel 120. The light-emitting region of the sub-pixel 120 may be a projection region of the sub-pixel 120 onto the glass substrate 11. This design approach may help uniform distribution of contact electrical current among the anode electrode 121.

In some other embodiments, the anode-electrode via 111 for the sub-pixel 120 in the first pixel row 12A may be located at other locations within the matched light-emitting region. The specific arrangement is not unnecessarily limited herein and may be selected per actual requirements.

In some embodiments of the present disclosure, the plurality of anode-electrode vias 111 for each row of repeating units 12 may be arranged among two rows in the second direction D2, and the plurality of anode-electrode vias 111 for each column of repeating units 12 may be arranged among two columns in the first direction D1, thereby reducing the via-drilling paths of the anode-electrode vias 111 in the row direction and thus increasing the via-drilling efficiency.

The light-emitting carrier board 10 may further include an encapsulation layer 15. The encapsulation layer 15 may be located on a side of the sub-pixel 120 away from the glass substrate 11. The material of the encapsulation layer 15 is not restricted herein and may be selected per actual requirements.

The light-emitting carrier board 10 may further include an isolation structure 17. The isolation structure 17 may be arranged on a side edge of the sub-pixel 120 for isolating the light-emitting layer 122 of the sub-pixel 120, thereby avoiding issues of pixel crosstalk. The isolation structure 17 may isolate the cathode electrode 123 of the sub-pixel 120, or may electrically connect the cathode electrodes 123 of adjacent sub-pixels 120. The material of the isolation structure 17 is not restricted herein and may be selected per actual requirements. In the present disclosure, the isolation structure 17 may also isolate the cathode electrode 123 of the sub-pixel 120. The cathode electrode 123 of the sub-pixel 120 may be an integral layer structure. The cathode electrode 123 may be located on a side of the isolation structure 17 away from the glass substrate 11.

As illustrated in FIG. 9, FIG. 9 is a schematic structural diagram of an embodiment of a display apparatus according to the present disclosure.

A display apparatus 300 may be provided in the present disclosure. The display apparatus 300 may include a mother board 200 and the above-mentioned display panel 100. The display apparatus 300 in embodiments of the present disclosure may be an active-matrix organic light-emitting diode (AMOLED).

The mother board 200 may be electrically connected to the display panel 100. The mother board 200 may be configured to transmit various required signals to the display panel 100, so as to control the display panel 100 to display images. The required signal may be for example a clock signal (CK), a low-potential signal (Vss), a power supply voltage signal (VDD), and a data signal (Data) required by the driving circuit layer.

In the above-mentioned embodiments, a description of each embodiment has its own focus, and a part not detailed in a certain embodiment may be referred to relevant descriptions of other embodiments.

The above are only implementations of the present disclosure, and do not limit the patent scope of the present disclosure. Any equivalent changes to the structure or processes made by the description and drawings of this application or directly or indirectly used in other related technical field are included in the protection scope of this application.

1. A display panel, comprising:
a silicon-based driving substrate;
a light-emitting carrier board, configured to be bonded to the silicon-based driving substrate, and comprising:
a glass substrate, comprising a plurality of anode-electrode vias;
a plurality of arrayed repeating units, arranged on a side surface of the glass substrate away from the silicon-based driving substrate; each of the repeating units comprises three sub-pixels with mutually different colors, the sub-pixels and the anode-electrode vias are arranged in one-to-one correspondence; the three sub-pixels with mutually different colors are defined as a first sub-pixel, a second sub-pixel, and a third sub-pixel, respectively; in each of the repeating units, the first sub-pixel and the second sub-pixel are arranged in a first direction to form a first pixel row, the third sub-pixel extends in the first direction to form a second pixel row, the first pixel row and the second pixel row are juxtaposed in a second direction; the first direction intersects with the second direction;
wherein three anode-electrode vias for each of the repeating units are arranged in a straight line in a preset direction, the preset direction is the first direction or the second direction; or
in each of the repeating units, two anode-electrode vias for the first pixel row are arranged in a straight line in the first direction, an anode-electrode via for the second pixel row and an anode-electrode via for the first pixel row are arranged in a straight line in the second direction.

2. The display panel as claimed in claim 1, wherein
in a direction parallel to the glass substrate, a sub-pixel and an anode-electrode via for the sub-pixel are arranged in a misaligned manner with respect to each other; the three anode-electrode vias for each of the repeating units are all located between the first pixel row and the second pixel row, and arranged in a straight line in the first direction; the three anode-electrode vias for each of the repeating units are equidistantly spaced in the first direction.

3. The display panel as claimed in claim 2, wherein
a side edge of the first sub-pixel away from the second sub-pixel is aligned with a first side edge of the third sub-pixel in the second direction; a side edge of the second sub-pixel away from the first sub-pixel is aligned with a second side edge of the third sub-pixel in the second direction; the first side edge and the second side edge are oppositely arranged in the first direction; an anode-electrode via for the first sub-pixel, an anode-electrode via for the third sub-pixel, and an anode-electrode via for the second sub-pixel are sequentially located at a ¼ position, a 2/4 position, and a ¾ position of the third sub-pixel in the first direction.

4. The display panel as claimed in claim 1, wherein
in a direction parallel to the glass substrate, a sub-pixel and an anode-electrode via for the sub-pixel are arranged in a misaligned manner with respect to each other; the three anode-electrode vias for each of the repeating units are arranged in a row in the second direction; two anode-electrode vias for the first pixel row are located between the first sub-pixel and the second sub-pixel, an anode-electrode via for the third sub-pixel is located between the first pixel row and the second pixel row.

5. The display panel as claimed in claim 1, wherein
a sub-pixel covers an anode-electrode via for the sub-pixel; the three anode-electrode vias for each of the repeating units are arranged in a row in the second direction; each of projection patterns of the first sub-pixel and the second sub-pixel onto the glass substrate is L-shaped, an orthographic projection of the first sub-pixel in the second direction partially coincides with an orthographic projection of the second sub-pixel in the second direction.

6. The display panel as claimed in claim 1, wherein
a sub-pixel covers an anode-electrode via for the sub-pixel; two anode-electrode vias for the first pixel row are arranged in a straight line in the first direction;
wherein an anode-electrode via for the third sub-pixel and an anode-electrode via for the first sub-pixel are arranged in a straight line in the second direction; or
the anode-electrode via for the third sub-pixel and an anode-electrode via for the second sub-pixel are arranged in a straight line in the second direction.

7. The display panel as claimed in claim 6, wherein
in the first pixel row, an anode-electrode via for a sub-pixel is located at a geometric center of a light-emitting region of the sub-pixel matching with the anode-electrode via.

8. The display panel as claimed in claim 1, wherein
in a direction parallel to the glass substrate, a repeating unit, the first pixel row, and the second pixel row are all rectangular or all parallelogram-shaped; the first sub-pixel and the third sub-pixel are centrally symmetrically arranged with respect to each other; and
a row direction of the repeating unit is the second direction; a column direction of the repeating unit is the first direction.

9. The display panel as claimed in claim 1, wherein
the first sub-pixel is a red sub-pixel, the second sub-pixel is a green sub-pixel, and the third sub-pixel is a blue sub-pixel.

10. The display panel as claimed in claim 1, wherein
the display panel further comprises anode electrode extension portions that are arranged in one-to-one correspondence with the anode-electrode vias; and
an anode electrode is electrically connected to an anode-electrode via through an anode electrode extension portion; the anode electrode extension portion and the anode electrode are formed by patterning a same conductive layer.

11. A display apparatus comprising a mother board and a display panel, wherein
the display panel comprises:
a silicon-based driving substrate;
a light-emitting carrier board, configured to be bonded to the silicon-based driving substrate, and comprising:
a glass substrate, comprising a plurality of anode-electrode vias;
a plurality of arrayed repeating units, arranged on a side surface of the glass substrate away from the silicon-based driving substrate; each of the repeating units comprises three sub-pixels with mutually different colors, the sub-pixels and the anode-electrode vias are arranged in one-to-one correspondence; the three sub-pixels with mutually different colors are defined as a first sub-pixel, a second sub-pixel, and a third sub-pixel, respectively; in each of the repeating units, the first sub-pixel and the second sub-pixel are arranged in a first direction to form a first pixel row, the third sub-pixel extends in the first direction to form a second pixel row, the first pixel row and the second pixel row are juxtaposed in a second direction; the first direction intersects with the second direction;
wherein three anode-electrode vias for each of the repeating units are arranged in a straight line in a preset direction, the preset direction is the first direction or the second direction; or
in each of the repeating units, two anode-electrode vias for the first pixel row are arranged in a straight line in the first direction, an anode-electrode via for the second pixel row and an anode-electrode via for the first pixel row are arranged in a straight line in the second direction.

12. The display apparatus as claimed in claim 11, wherein
in a direction parallel to the glass substrate, a sub-pixel and an anode-electrode via for the sub-pixel are arranged in a misaligned manner with respect to each other; the three anode-electrode vias for each of the repeating units are all located between the first pixel row and the second pixel row, and arranged in a straight line in the first direction; the three anode-electrode vias for each of the repeating units are equidistantly spaced in the first direction.

13. The display apparatus as claimed in claim 12, wherein
a side edge of the first sub-pixel away from the second sub-pixel is aligned with a first side edge of the third sub-pixel in the second direction; a side edge of the second sub-pixel away from the first sub-pixel is aligned with a second side edge of the third sub-pixel in the second direction; the first side edge and the second side edge are oppositely arranged in the first direction; an anode-electrode via for the first sub-pixel, an anode-electrode via for the third sub-pixel, and an anode-electrode via for the second sub-pixel are sequentially located at a ¼ position, a 2/4 position, and a ¾ position of the third sub-pixel in the first direction.

14. The display apparatus as claimed in claim 11, wherein
in a direction parallel to the glass substrate, a sub-pixel and an anode-electrode via for the sub-pixel are arranged in a misaligned manner with respect to each other; the three anode-electrode vias for each of the repeating units are arranged in a row in the second direction; two anode-electrode vias for the first pixel row are located between the first sub-pixel and the second sub-pixel, an anode-electrode via for the third sub-pixel is located between the first pixel row and the second pixel row.

15. The display apparatus as claimed in claim 11, wherein
a sub-pixel covers an anode-electrode via for the sub-pixel; the three anode-electrode vias for each of the repeating units are arranged in a row in the second direction; each of projection patterns of the first sub-pixel and the second sub-pixel onto the glass substrate is L-shaped, an orthographic projection of the first sub-pixel in the second direction partially coincides with an orthographic projection of the second sub-pixel in the second direction.

16. The display apparatus as claimed in claim 11, wherein
a sub-pixel covers an anode-electrode via for the sub-pixel; two anode-electrode vias for the first pixel row are arranged in a straight line in the first direction;
wherein an anode-electrode via for the third sub-pixel and an anode-electrode via for the first sub-pixel are arranged in a straight line in the second direction; or
the anode-electrode via for the third sub-pixel and an anode-electrode via for the second sub-pixel are arranged in a straight line in the second direction.

17. The display apparatus as claimed in claim 16, wherein
in the first pixel row, an anode-electrode via for a sub-pixel is located at a geometric center of a light-emitting region of the sub-pixel matching with the anode-electrode via.

18. The display apparatus as claimed in claim 11, wherein
in a direction parallel to the glass substrate, a repeating unit, the first pixel row, and the second pixel row are all rectangular or all parallelogram-shaped; the first sub-pixel and the third sub-pixel are centrally symmetrically arranged with respect to each other; and
a row direction of the repeating unit is the second direction; a column direction of the repeating unit is the first direction.

19. The display apparatus as claimed in claim 11, wherein
the first sub-pixel is a red sub-pixel, the second sub-pixel is a green sub-pixel, and the third sub-pixel is a blue sub-pixel.

20. The display apparatus as claimed in claim 11, wherein
the display panel further comprises anode electrode extension portions that are arranged in one-to-one correspondence with the anode-electrode vias; and
an anode electrode is electrically connected to an anode-electrode via through an anode electrode extension portion; the anode electrode extension portion and the anode electrode are formed by patterning a same conductive layer.
